(19) United States
(12) Patent Application Publication
(10) Pub. No.: US 2004/0089237 A1
(43) Pub. Date: May 13, 2004

(54) Continuous chemical vapor deposition process and process furnace

(76) Inventors: James Gary Pruett, Cypress, CA (US); Shrikant Awasthi, Cerritos, CA (US)

Correspondence Address: JOSEPH G CURATOLO, ESQ., RENNER KENNER GREIVE BOBAK TAYLOR & WEBER, 24500 CENTER RIDGE ROAD, SUITE 280, WESTLAKE, OH, 44145, US

(21) Appl. No.: 10/621,478

(22) Filed: Jul. 17, 2003

Related U.S. Application Data
(60) Provisional application No. 60/396,522, filed on Jul. 17, 2002.

(51) Int. Cl. C23C 16/00

(52) U.S. Cl. 118/719; 118/718

(57) ABSTRACT

An apparatus and process is provided for continuously depositing solid carbon at atmospheric pressure onto the surfaces and in the porosity of a thin substrate material.

### BACKGROUND

Isothermal chemical vapor deposition of carbon onto a substrate material is currently practiced in large, high temperature batch vacuum furnaces by placing or arranging the materials or objects to be treated within the volume of a furnace, closing the furnace, evacuating the furnace, heating the furnace, and introducing process gases into the furnace for a duration of time and at a temperature and at a gas flow rate sufficient to achieve desirable coating or infiltration of the substrate materials within the batch vacuum furnace. The furnace must be cooled to remove the processed materials.

Due to the sizes and irregular shapes of the substrate materials being processed, the inside of the batch vacuum furnace unavoidably has unfilled regions that are prone to allowing unrestricted decomposition of the process gas to form undesirable gaseous products, which lead to the formation of tars and soots. These gaseous products are capable of forming thick, sealing carbon surfaces on the substrate material being processed, or of forming sooty deposits on the inside walls of the furnace, which can cause process failure.

Increasing the concentration and temperature of the hydrocarbon process gas, the transit time of the hydrocarbon process gas in the hot zone and the distance from the process gas from surfaces, all increase the above described unwanted gas side reactions. In addition, decreasing the surface area available for carbon deposition also increases these unwanted side reactions.

The operation of chemical vapor deposition processes in a batch vacuum furnace, therefore, places limitations on the achievable coating and/or infiltration rates due to the unfilled volume regions of the batch vacuum furnace. The net result is that the process conditions must be scaled back from faster process conditions that actually might achieve proper or desired deposition of materials, in order to decrease the occurrence of the above described undesirable, sealing or sooting gas side reactions.

An additional factor in this practice, is that the process gas must flow through the batch vacuum furnace at a sufficient rate so that residence times of the gas in the furnace longer than a few seconds are rare or non-existent, in order to avoid the previously described undesirable gas side reactions. The flow rate of the gas in the furnace, coupled with the low reaction rate of the gas within the furnace, leads to a very low hydrocarbon use efficiency. Under these process conditions, the hydrocarbon use efficiency is less than about 10%. As such, the process exhaust gas remains very rich in hydrocarbons, resulting upon cooling of the process gas, in considerable tar deposits in downstream elements, including valves, pipes, pumps, and the like. This process gas must be contained and vented to pollution control devices to clean up the process gas exhaust. This additional maintenance adds considerable cost and time to the operation of the manufacturing process.

Another factor in this practice, is that not all substrate materials being processed “see” or are exposed to the same local environment within the batch vacuum furnace, which results in undesirable, non-uniform deposition of carbon on and in the substrate materials. Also, the low concentration of the process gas necessary to avoid the unwanted gas side reactions has only been practically achieved by using a vacuum furnace system to reduce concentrations to acceptable levels.

These limitations are especially relevant when processing relatively thin substrate materials, whose thickness is below about 0.25 inches, and become even more relevant for processing substantially single fabric plies whose thickness is about 0.04 inches or less. For such thin substrate materials, the constraint recognized by the industry that deposition rates must be small to avoid coating the exterior surfaces of the part being processed without depositing carbon on the inside walls of the furnace no longer strongly applies. Such materials are capable of being effectively infiltrated at much higher rates. However, to process thin materials in large batch vacuum furnaces, it has become commonplace in the industry to stack the thin material to be processed into a relatively thick stack, in order to approximate the thickness of the thickest parts normally processed in the batch vacuum furnaces. This is done in order to achieve both maximum furnace loading density of such parts to be processed, and for compatibility with the processing rate in such batch vacuum furnaces, which can then be run substantially under conditions selected to avoid the occurrence of adverse gas side reaction problems.

A continuous deposition process generally results in improved product uniformity, as compared to batch processes. Furthermore, furnace operations running at atmospheric pressure reduces the overall process complexity and cost, as compared to a furnace operation running under vacuum conditions. There remains, therefore, a need for a chemical vapor deposition process with improved hydrocarbon process gas use efficiency, improved uniformity of carbon deposition onto and/or into substrate materials, faster processing time for thin materials and reduced process complexity and cost.

Several attempts have been made in the prior art to provide efficient continuous chemical vapor deposition processes. U.S. Pat. No. 3,944,686 to Froberg describes a low pressure continuous deposition process, which requires vacuum isolation plenums to maintain the low pressure required in the process zone. The chemical vapor deposition process described by Froberg, however, is not an atmospheric pressure process. Nor is any provision made by Froberg to moderate the extensive hydrocarbon gas decomposition and formation of soot and tars produced by the side reactions. The process taught by Froberg is subject to the same process limitations as previously described for the batch process. Extensive deposition of carbon on the critical gas inlet components of the Froberg process would also be expected to make the process non-economical to practice, due to extensive maintenance required on such a system.

U.S. Pat. No. 5,364,660 to Gabor describes a process for coating of fibers and fabric strips suitable for putting thin layers of different material onto forms. The Gabor process does not, however, teach to balance the gas input to achieve high use efficiency of any hydrocarbon gas, nor does it teach techniques to substantially eliminate formations of soots or tars. In fact, Gabor specifically mentions the requirement to keep the tube short in order to be able to clean the furnace of such soot and tar material.

Therefore, there remains a need in the art for the provision of a chemical vapor deposition process that can efficiently and cost effectively deposit a desired amount of pyrocarbon material onto and/or into a substrate at atmospheric pressure and in a fast, uniform and continuous manner.

### SUMMARY

A continuous process furnace for the deposition of carbon onto a substrate material is provided, comprising a pre-deposition zone for accepting the substrate material and contacting the substrate material with a process gas at a temperature below the carbon deposition temperature, wherein the process gas comprises a decomposable carbon-containing species; a carbon deposition zone in communication with the pre-deposition zone, wherein the walls of the deposition zone are spaced apart from the surface of the substrate, when present, by a distance that is small enough to allow convective and diffusive transport of the process gas to the substrate to permit substantially uniform deposition of pyrocarbon at least one of i) into pores of the substrate or ii) onto the surface of the substrate at the carbon decomposition temperature in preference to the decomposition of the process gas to produce soot and tar.

Also provided is a continuous process for the deposition of pyrocarbon at least one of i) into pores of a substrate material or ii) onto the surface of the substrate material comprising: introducing the substrate material into a process furnace; the process furnace comprising a pre-deposition zone for accepting the substrate material and, a carbon deposition zone in communication with the pre-deposition zone, wherein the walls of the deposition zone are spaced apart from the surface of the substrate, when present, by a distance that is small enough to allow convective and diffusive transport of the process gas to the substrate to permit substantially uniform deposition of pyrocarbon at least one of i) into pores of the substrate material or ii) onto the surface of the substrate material at the carbon decomposition temperature in preference to the decomposition of the process gas to produce soot and tar; introducing a process gas into the pre-deposition zone; and contacting the substrate material in the pre-deposition zone with the process gas at a temperature below the carbon deposition temperature, wherein the process gas comprises a decomposable carbon-containing species; passing the substrate material to the carbon deposition zone and heating the deposition zone to a temperature sufficient to cause decomposition of the decomposable carbon-containing species and substantially uniform deposition of pyrocarbon at least one of (i) in the pores of or (ii) on the surface of the substrate material.

Also provided is a substantially uniformly carbon-densified or carbon-coated substrate material product produced by a continuous carbon deposition process comprising: introducing the substrate material into a process furnace; the process furnace comprising a pre-deposition zone for accepting the substrate material and, a carbon deposition zone in communication with the pre-deposition zone, wherein the walls of the deposition zone are spaced apart from the surface of the substrate, when present, by a distance that is small enough to allow convective and diffusive transport of the process gas to the substrate to permit substantially uniform deposition of pyrocarbon at least one of i) into pores of the substrate material or ii) onto the surface of the substrate material at the carbon decomposition temperature in preference to the decomposition of the process gas to produce soot and tar; introducing a process gas into the pre-deposition zone; contacting the substrate material in the pre-deposition zone with the process gas at a temperature below the carbon deposition temperature, wherein the process gas comprises a decomposable carbon-containing species; passing the substrate material to the carbon deposition zone and heating the deposition zone to a temperature sufficient to cause decomposition of the decomposable carbon-containing species and substantially uniform deposition of pyrocarbon at least one of in the pores of or on the surface of the substrate material.

A continuous roll composite material is also provided, comprising a fibrous substrate having a pyrocarbon addition that is either (i) coated onto the fibrous substrate and/or (ii) infiltrated into the porosity of the fibrous substrate, wherein the variation in the mass of the pyrocarbon addition that is infiltrated into and/or coated onto the substrate is less than about 20 percent, as measured as a 2 square foot section taken at various portions of the continuous roll.

We have now discovered that the extent of process gas side reactions, which can occur at different rates in different portions of a large batch vacuum furnace, is effected by five general process conditions, namely, (1) the molar concentrations of the hydrocarbon process gas, (2) the temperature of the hydrocarbon process gas, (3) the transit time of the hydrocarbon process gas in the hot zone of the furnace, (4) the surface area available for carbon deposition and (5) the distance of the hydrocarbon process gas to the nearest surface available for carbon deposition. The process furnace and deposition process disclosed herein substantially overcome the limitations of batch vacuum furnace processes by optimizing the above described process conditions, thereby substantially eliminating the formation of soots and tars caused by the process gas side reactions.

Unlike U.S. Pat. No. 5,364,660 to Gabor, this process puts no restrictions on the length of the apparatus. Therefore, unlike Gabor, the present invention puts no limit on the size or amount of densified or coated material. In fact, while the Gabor process is capable of applying thin coatings, it is not suitable for full densification of porous parts as is this process. Moreover, Gabor does not teach to provide a sufficient surface area to furnace volume ratio in order to increase deposition of carbon onto a substrate and to substantially eliminate the formation of soot and tar. Neither Gabor nor Froberg recognize the ability to control the surface area of substrate to volume in the furnace in order to limit side reactions and thereby provide an efficient and cost effective solution to the competitive side reactions that the hydrocarbon process gas can undergo.

### BRIEF DESCRIPTION OF THE DRAWINGS

FIG. 1 is a side sectional view of a schematic representation of one embodiment of the process furnace.

FIGS. 2A, 2B and 2C are cross sectional views of a schematic representation of three embodiments of the process furnace.

### DETAILED DESCRIPTION OF THE PREFERRED EMBODIMENTS

The present invention relates to the deposition of materials at atmospheric pressure using a continuous chemical vapor deposition process. We have discovered a process and furnace conditions that drive the chemical vapor deposition process for the deposition of pyrocarbon away from undesirable gas side reactions, and toward increased deposition of pyrocarbon on and/or in a thin substrate material. A continuous system for depositing pyrolytic carbon on and/or in relatively thin substrate materials is provided. The furnace and process is used for continuous processing of thin materials to infiltrate and/or to coat the substrate materials with solid pyrocarbon. The process can be used to deposit solid pyrocarbon on surfaces, or infiltrate carbon within the porosity of any substrate material that can be introduced into the process furnace in a substantially flat form or a shape comprising flat walls, or that can be provided as a thin, substantially flat part or a part comprising flat walls on a carrier sheet or web.

The substrate material to be processed may be thin, porous materials to be densified with carbon. Once densified with pyrocarbon, the densified substrate materials may be used for clutch plates, brakes or other friction members, whose dimensions are less than about ½ inch thick. Substrate materials, such as sheets, fabrics and felts, which can be continuously fed through the process from a stock roll and taken up at the end of the process with another roll or fed into additional sheet processing operations, may also be utilized. The only requirements of the substrate material onto which the pyrocarbon is deposited is that it has substantially flat dimensions, and that it is comprised of a material that is sufficiently stable at the process conditions to allow the process to proceed without damage to the substrate material, which would restrict its intended use. By way of example, but not by limitation, the process is useful for preparing carbon-coated or at least partially densified, woven or non-woven fabrics, knitted fabrics, felts, papers, sheets or blankets of carbon, glass, ceramic, or metal fibers or other fibrous materials, as discussed in more detail below.

The term “pyrocarbon,” as used throughout the specification, refers to solid carbon that is substantially uniformly deposited on the surfaces and/or in the porosity of the substrate material as a result of heating and decomposing a carbon-containing process gas. The terms “carbon” or “pyrolytic carbon” can be used interchangeably with the term “pyrocarbon.”

The terms “continuous” or “continuously” refer to a deposition process where the substrate material is advanced along a transverse path through the process furnace without requiring an interruption of the process to remove the processed material product. The terms “continuous” and “continuously” are intended to encompass those deposition processes where the transverse travel of the substrate material through the furnace does not stop, as well as those that may be intermittently or briefly halted while the process is still operating. The continuous deposition process is distinguished from conventional batch processes where a part is placed in the batch vacuum furnace to be processed and, after processing of the part, the batch furnace must be cooled, opened and the processed parts removed before new parts to be processed can be loaded in the furnace for processing.

The process furnace generally includes means for introducing a carbon-containing process gas into the process furnace, means for advancing substrate materials to be processed through the furnace, means for heating the furnace and means for removing or otherwise expelling exhaust gas from the process furnace. The process furnace includes a specially designed deposition zone to maximize utilization of hydrocarbon in the process gas, to substantially avoid most gas side reactions and, thus, to effect deposition conditions which significantly reduce the processing time of the thin substrate materials and to minimize the environmentally problematic exhaust waste streams. In one embodiment, the process furnace is designed such that no gas regions are formed within the deposition zone of the furnace, which are more than about 1 inch away from an inner furnace wall or an external surface of the substrate material being processed.

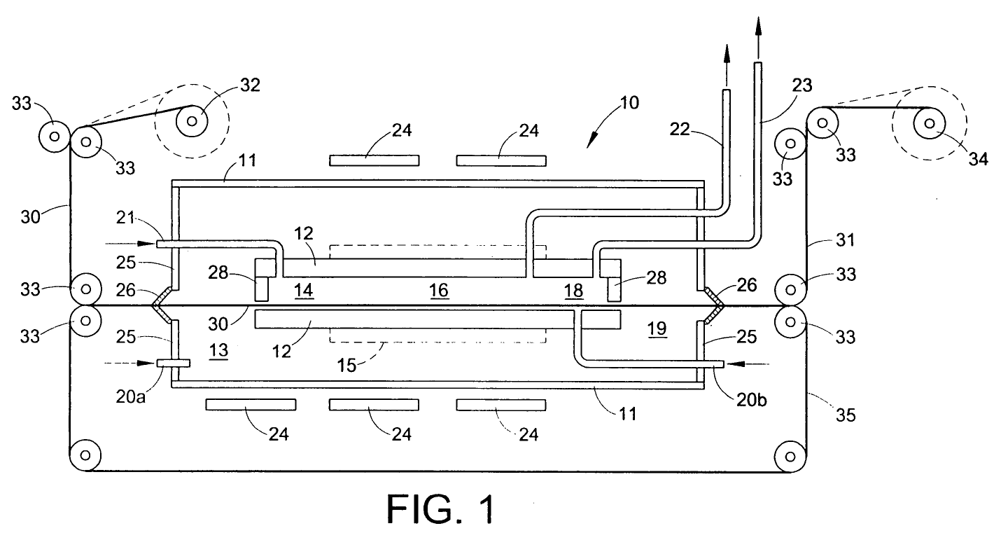

Referring to FIG. 1, the process furnace 10 includes an outer process furnace tube 11. Located within the inner volume of outer process furnace tube 11 is inner process furnace retort 12. The process furnace 10 includes a pre-deposition region or zone 14 having an opening to receive a thin substrate material 30 to be processed. The pre-deposition region 14 of the process furnace 10 has a process gas inlet and may include a means 21 for introducing the process gas, namely a carbon-containing gas, into the inner process furnace retort 12. The means 21 for introducing a process gas into the process furnace may be an inlet line, piping, tubing, or the like, having an inner volume and that is capable of introducing a gas source from the outside environment into the interior of the process furnace retort 12. This pre-deposition region 14 is located outside of the high temperature deposition zone 16 of the inner process furnace retort 12, so that its temperature is maintained at a value below the temperature that is necessary to cause a hydrocarbon gas to decompose. In one embodiment, the temperature of the pre-deposition region 14 of the process furnace retort 12 is maintained at a temperature of about 500° C. or less. In another embodiment, the temperature of the pre-deposition region 14 of the process furnace retort 12 is maintained at a temperature of about 200° C. or less.

During the continuous deposition process, the carbon-containing process gas is introduced to the substrate material 30 in the pre-deposition zone 14 of the process furnace retort 12. Introducing the process gas to the starting substrate material 30 in the pre-deposition region 14 of the process furnace retort 12 substantially eliminates the uncontrolled decomposition of the process gas in the process gas inlet lines or gas jets, experienced when typically used to introduce process gases to a hot processing chamber or region, and where decomposing gases do not have direct access to the material being processed. The inner volume of the pre-deposition zone 14 of the process furnace retort 12 can be large so as to decrease the flow rate of the process gas into the hot zone 15 so as to permit the process gas to pre-heat, up to a temperature slightly below the decomposition temperature.

Still referring to FIG. 1, downstream from the pre-deposition region 14, the process furnace retort 12 includes a high temperature carbon deposition region 16 into which the starting substrate material 30 being processed is fed, and where the carbon-containing process gas is heated to a temperature sufficient to decompose the carbon-containing species in the gas and to coat or to infiltrate the starting substrate material 30 with solid pyrocarbon. The high temperature deposition region 16 of the process furnace retort 12 is constructed such that the flow of the process gas is confined to a small region surrounding the outer surfaces of the substrate material 30. In one embodiment, the dimensions of the high temperature deposition region 16 of the process furnace retort 12 are constructed such that the flow of the process gas never exceeds about 1 inch (2.54 cm) from the outer surfaces of the substrate material 30. In another embodiment, the dimensions of the high temperature deposition region 16 of the inner process furnace retort 12 are constructed such that the flow of the process gas does not exceed greater than about ¼ inch (0.64 cm) from the outer surfaces of the starting substrate material 30. In this manner, the process gas is always maintained in sufficiently close proximity to the surfaces of the substrate material being processed, such that unwanted gas side reactions forming tar or soot are minimized, and the gas is substantially used to preferentially deposit solid carbon on or in the substrate material being processed.

Near the downstream end of the high temperature carbon deposition zone 16 of the process furnace retort 12, an exhaust port 22 may optionally be provided to exhaust hot gases prior to the end of the deposition zone 16. The optional exhaust gas port 22 is used particularly in processes where insufficient hydrocarbon has been removed from the process gas, so that the gas which might otherwise form tars or particulate soot when cooled, may be removed from the process furnace retort 12 while still hot to avoid damaging the desired surface quality of the substrate material 30 being processed.

Downstream from the high temperature deposition region 16, is an optional cooling zone 18, which is maintained at a temperature lower than the temperature of the high temperature deposition zone 16. The temperature of the optional cooling zone 18 can be maintained at a temperature that is comparable to the pre-deposition zone 14 that is located upstream from the high temperature deposition region 16 of the process furnace 10. Generally, no direct heating of the substrate material 30 takes place in the cooling region 18, and the temperature is allowed to cool to a temperature below about 500° C. In another embodiment, the temperature is allowed to cool to a temperature below about 200° C. Near the end of the optional cooling zone 18 there is provided a gas exhaust port 23 to remove the remaining process gas, if necessary to appropriate pollution control devices, or to the ambient environment.

In another embodiment, an inlet 20b for introducing an inert gas into the cooling region 18 may optionally be provided to further eliminate the condensation problems resulting from the cooling of the unreacted hydrocarbon process gas.

The process furnace retort 12 may be constructed of any material compatible with the temperatures, pressures and gases used in the continuous chemical vapor deposition process. The process furnace retort 12 should be constructed from a material which is highly resistant to oxidative attack. Resistance to oxidation permits periodic cleaning of the interior surfaces of the process furnace by introducing air, oxygen, or steam into the process chamber while the process furnace is hot, to oxidize and remove any carbon deposits accumulated from normal operation of the process furnace. Suitable materials from which the process furnace retort 12 can be constructed include, but are not limited to, quartz, ceramic materials, such as alumina, mullite, silicon carbide and the like, oxidation resistant metals and oxidation resistant metal alloys. Useful oxidation resistant metal alloys include, but are not limited to, stainless steel and MONEL™ metal alloy. In one embodiment, the material used to construct the process furnace retort 12 is alumina.

The process furnace 10 includes means 24 for heating the pre-deposition zone 14 and the deposition hot zone 16. Gas/flame heaters and electrical resistance heaters may used to heat the pre-deposition zone 14 and deposition hot zone 16 of the process furnace 10. Gas/flame heaters and electrical resistance heaters using metal heating elements are useful for heating the process furnace 10 to temperatures up to about 900° C. to about 1,000° C. For deposition processes requiring heating of the process furnace 10 to temperatures of about 1,100° C. and above, electrical resistance heaters using ceramic heating elements are useful. When electrical resistance heaters having ceramic heating elements are used to heat the process furnace 10, the ceramic material comprising the heating element is preferably silicon carbide. In accordance with the inventive process, the heating element may be in the form of a silicon carbide heating rod.

According to the process, the starting substrate material 30 to be processed is generally provided in a relatively thin, flat form, such as continuous sheets, plates and patterned shapes. The continuous sheets can be provided in the form of blankets, fabrics, felts, papers, webs and the like. If the substrate material is provided as individual pieces, then the individual pieces may be disposed, in a uniformly distributed manner, on a carrier sheet, web or screen that can carry the individual pieces from the ambient environment into the process furnace for processing. The carrier should allow the process gas access to the underside of the carried substrate pieces. The starting substrate material must be capable of being transported through the process furnace 10 in such a way that, in the carbon deposition region 16, no region of the process gas is more than about 1 inch (2.54 cm) from any inner wall of the inner process retort 12 or any of the surfaces of the starting substrate materials being processed.

If the starting substrate material requires any preheating treatment to further stabilize the starting substrate material relative to the process conditions during pyrocarbon deposition, then the substrate material may be fed, preferably in a substantially continuous manner, through a normal heat-treating processing furnace. This heat-treating continuous processing furnace is designed to prevent the hot substrate material from coming into contact with an oxidizing atmosphere. It should be understood that this is merely an optional step of the process, and may or may not need to be performed, depending on the composition of the starting substrate material.

Prior to entry into the process furnace 10, the starting substrate material 30 may be introduced into an isolating chamber 13. According to this embodiment, the leading edge of the starting substrate material 30 is fed into an isolating chamber 13 through a narrow opening, such as a slit. The opening of the isolating chamber 13 may incorporate additional elements, such as sealing elements 26. The sealing elements 26 may be provided in the form of loose fitting covers or padding, or automatically opening and closing means to permit passage of individual articles. The purpose of the sealing covers, padding, or opening and closing means is to substantially limit the transfer of gas into the isolation chamber 13 through the opening. Once the starting substrate material 30 has been fed into the isolating chamber 13, a flow of inert gas, such as nitrogen, is introduced into the isolating chamber 13 to purge the isolating chamber 13 of any air. The isolating chamber 13 is maintained at a positive pressure relative to the ambient environment to further restrict the flow of air into the isolating chamber 13. The use of the isolating chamber 13 is an optional part of the process, which may not be required in order to process every substrate material. It should also be noted that the isolating chamber 13 may be used with the process chamber (ie—inner furnace retort) 12 alone, or in combination with the process chamber 12 and the above described optional heat-treating processing furnace.

In an alternative embodiment, in lieu of the use of an isolating chamber 13, a ventilation system that is capable of exhausting process gas fumes in an appropriate manner may be utilized, such that process gases are allowed to escape the process furnace in such a manner that air is not able to enter the inner process retort 12 of the process furnace 10.

From either the isolating chamber 13 or exhaust area, the substrate material 30 is introduced into the pre-deposition zone 14 and fed through the high temperature carbon deposition zone 16 through another small slit. The high temperature deposition zone 16 may also incorporate further gas-flow restricting, sealing elements 28, such as covers, padding, baffles or opening and closing members or plates to limit gas flow between the process chamber 12 and the isolating chamber 13 or exhaust area.

As the substrate material is fed through the process furnace retort 12, a carbon-containing process gas is introduced into the process furnace retort 12. As the substrate material 30 is fed through the process furnace retort 12, the surfaces of the substrate material 30 are exposed to the carbon-containing process gas. The carbon-containing process gas is heated to a temperature sufficient to decompose the carbon-containing species in the process gas, and solid pyrocarbon is deposited on the surfaces of the substrate material 30. According to this process, the term “deposition” is intended to encompass at least one of (i) coating the outer surfaces of the substrate material with solid pyrocarbon, and (ii) infiltrating the porosity of the substrate material with pyrocarbon. In one embodiment, deposition refers to processes whereby a porous substrate material is both infiltrated with pyrocarbon and its outer surface is also coated with a desired amount of pyrocarbon.

The process furnace 10 includes a means for continuously advancing the substrate material 30 through the process furnace 10. In one embodiment, where the substrate material 30 is provided as a continuous sheet or web, the means for continuously advancing the substrate material 30 through the process furnace 10 can include a reel-to-reel system, which includes a feed reel 32 and a take-up reel 34. According to this embodiment, the starting substrate material 30 is wound on the feed reel 32. The reel-to-reel system may include means for advancing the starting substrate material 30 from the feed reel, through the process furnace 10 to the take-up reel 34. As the substrate material 30 is being advanced through the process furnace 10, the desired densification of the substrate material 30 occurs in the high temperature carbon deposition zone 16. The densified product 31 is then wound, such as in a counter-clockwise fashion, on the take-up reel 34.

Alternatively, individual pieces of thin substrate material 30 may be advanced through the process furnace 10 on a conveyer means 35. The conveyor means 35 may include a belt loop system that is capable of advancing substrate materials 30 to be processed into and out of the process furnace 10. The belt may be constructed of an oxidation resistant material, such as stainless steel or MONEL™ metal alloy. The conveyor belt 35 is generally provided in a form of an open screen or mesh construction to permit access of the reactive process gas to all exterior surfaces of the starting substrate materials.

The process gas utilized may be selected from any gaseous decomposable hydrocarbon or mixture thereof, or vapors carried from a solid or liquid hydrocarbon precursor or mixture of precursors maintained at a temperature to give adequate vapor pressure to provide process gas flow.

The process gas utilized in the continuous chemical vapor deposition process is comprised at least partially of a hydrocarbon gas. Useful hydrocarbon gases include natural gas, straight chain, branched, or cyclic alkanes, such as ethane, propane, butane, pentane, cyclopentane, hexane and cyclohexane; alkenes, such as ethylene, propylene, and butylene; alkynes, such as acetylene; aromatic hydrocarbons such as benzene; and mixtures thereof. In one embodiment, the process gas utilized in the continuous chemical vapor deposition process is propane.

The process gas may contain some amount of diluent inert gas, up to 98% inert gas, but preferably containing below 50% inert gas and more preferably containing below 10% inert gas. The inert gas may be nitrogen, argon, or another noble gas or mixtures thereof. As shown in FIG. 1, the diluent inert gas may be introduced into the process furnace 10 by an inert gas inlet means 20a.

The hydrocarbon gas concentration and net gas flow rate are maintained at controlled values, which could optionally be varied during processing, but is generally set such that sufficient carbon deposition occurs in the high temperature carbon deposition zone 16 of the process furnace retort 12 to achieve target pyrocarbon deposition rates. The process gas flow is regulated to allow sufficient residence time within the high temperature carbon deposition zone 16 to allow carbon deposition of greater than 5% of the decomposable carbon-containing species in the process gas. In another embodiment, the process gas flow is regulated to allow sufficient residence time within the high temperature carbon deposition zone 16 to allow carbon deposition of greater than 50% of the decomposable carbon-containing species in the process gas. In still another embodiment, the process gas flow is regulated to allow sufficient residence time within the high temperature carbon deposition zone 16 to allow carbon deposition of greater than 80% of the decomposable carbon-containing species in the process gas.

The high temperature deposition region 16, also referred to as the hot zone or the deposition zone of the process furnace retort 12, is heated to a temperature sufficient to cause decomposition of the decomposable carbon-containing species in the process gas to form solid carbon on the surfaces and/or in the porosity of the substrate material 30 being processed. The temperature of the high temperature deposition zone 16 of the process furnace retort 12 can be as high as is possible within the compatibilities of the heating system and substrate materials to achieve the deposition process. We have found no practical limit to the temperature with regard to the deposition process itself, and expect that temperatures achieved in pyrocarbon coating operations using other methods would be achievable in this process. The temperature of the high temperature deposition zone 16 is at least about 900° C. In another embodiment, the temperature of the high temperature deposition zone 16 is at least about 1000° C. In a further embodiment, the temperature of the high temperature deposition zone 16 is at least about 1100° C. The temperature profile of the high temperature carbon deposition zone 16 can be controlled to regulate the extent of reaction of the process gas in various regions of the high temperature carbon deposition zone 16 in order to provide beneficial product results. The overall length of the hot deposition zone can be made any value, but is preferably designed to obtain a beneficial processing time as the substrate material proceeds through the hot zone at a designed rate of speed.

The length of the high temperature deposition zone and the rate of the movement of substrate material through the deposition zone is designed to obtain the desired amount of carbon deposition on and/or in the substrate material and to meet the target production rate. Because the elements of the process furnace allow significantly higher processing rates than are achievable in batch furnaces, the length of the furnace can be substantially shorter to achieve the desired final product as compared to what would be necessary if the process rate was held to a value similar to rates achieved in conventional batch vacuum processing. For example, using current batch processing conditions, a thin sheet fabric material is processed to desired density in about 300 to about 400 hours of processing time. Using the inventive furnace and process, the same material can be processed to a desired target density in less than about 6 hours of processing time. Thus, a furnace designed to achieve the same throughput of material using the conventional batch furnace process conditions would have to have a carbon deposition zone at least 50 feet long for every foot of length of carbon deposition zone in a furnace using the inventive process.

The rate of travel of the substrate material through the carbon deposition zone is significantly increased as a result of the process conditions possible with the present invention. Because the control, by the inventive process, of the process gas side reactions allows operation under much more aggressive deposition conditions, the significant decrease in process time required for deposition allows a significant increase in the rate of travel of the substrate through a furnace of a given length deposition hot zone. The direct correlation between the process time allowed, travel speed, and deposition hot zone length allows significant latitude in creating a system to practice the invention. Without being bound to any particular theory, it is estimated that a throughput of about 50 linear yards of continuous sheet or fabric material per day can be accomplished with about a 3 hour processing (residence) time using about a 10 foot long deposition zone process furnace. The output could be increased to about 100 linear yards per day by doubling the deposition hot zone length. Thus, the length of the furnace and, therefore, the line speed can be entirely determined by the required processing time. This processing time is significantly shorter than times required for conventional batch processing, thus allowing significant decreases both in deposition hot zone length and turndowns in line speed.

After processing, the substrate material 30 having a desired quantity of solid pyrocarbon deposited thereon exits from the process furnace retort 12 through a narrow opening that is similar to the inlet opening. Again, the exit outlet opening may include additional gas-restricting sealing, covering, packing or blocking means 26. The outlet opening allows the material to pass into another optional isolating chamber 19, which may optionally be the same chamber as, or in communication with, the initial isolating chamber 13. This isolating chamber 19 is purged with inert gas, which is generally maintained at a pressure necessary to block passage of process gas from the deposition region 16 of the process furnace retort 12 into the isolation chamber 19, and to block passage of gases in the ambient environment into the isolating chamber 19. The temperature of the isolating chamber 19 is generally reduced to about 500° C. to about 200° C. In lieu of this optional chamber, the exit portion of the system can be serviced by a ventilation system to exhaust the expended process gas in such a way that air cannot flow into the process chamber.

The processed material 31 exits the optional isolation chamber 19, preferably through a narrow outlet opening and returns to the ambient atmosphere. At this point, the product may optionally be supplied to additional in-line processing equipment such as surface finishing stages, splicing and unsplicing stages, defect removal stages, testing stages, and final product packaging stages. Means may be provided at least at one point along the exit region of the process line, to draw the product material from the initial feed system into the process through appropriate opposed rollers 33, pullers, or other suitable means, to provide a smooth and uniform rate of motion or regular incremental or stepped motion of material through the process.

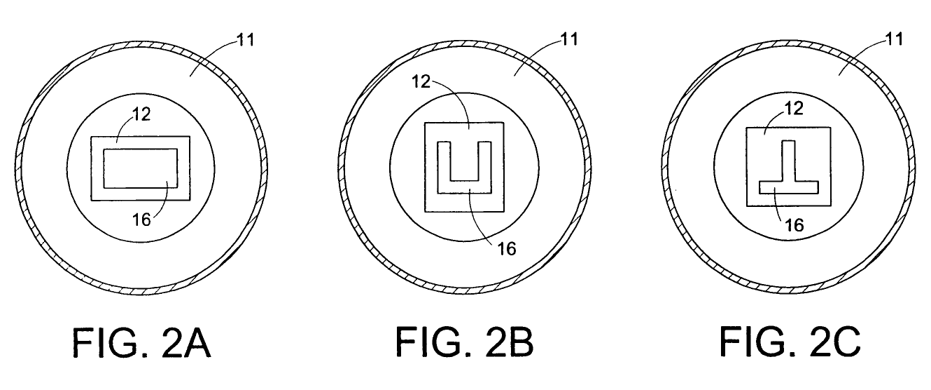

The process furnace retort 12 shown in FIGS. 1 and 2A has a generally rectangular cross section. It should be noted, however, that the process furnace 10 can comprise various configurations for processing various shaped substrate materials. The process furnace retort 12, for example, may comprise in cross section, an annular shape, U-shape, T-shape or finned shape for processing annular, U-shaped, T-shaped or finned-shaped substrate materials, respectively. FIGS. 2A-2C show, in cross section, a rectangular, a U-shaped, and a T-shaped process furnace, respectively. The process furnace retort 12 generally maintains a substantially constant cross section along the entire length of the carbon deposition hot zone of the furnace that is similar to the cross sectional shape of the substrate being processed, such that the shaped substrate materials can be continuously and freely passed through the process furnace retort 12 during processing, without exceeding the desired distance from the surface to the furnace wall.

The process furnace 10 may be switched periodically from the process gas to an oxidizing gas such as air, steam, or oxygen in order to subject the process chamber to an oxidizing atmosphere to remove any carbon deposits from the process furnace. During such cleaning cycles, the material being processed would be interrupted and replaced with a leader material made from a similarly oxidation resistant material, such as a ceramic cloth, metal cloth or metal mesh. To oxidize any carbon deposits that may have formed on the inner walls of the process furnace, a silica fabric leader is preferably used in combination with an oxidizing gas, such as air, steam, or oxygen.

The starting substrate material may be in the form of woven fabrics, knitted fabrics, non-woven fabrics, felts, papers, blankets, mats, webs, or similar porous sheet-like materials. The starting material could also be an arrangement of substantially thin individual parts, which could be arranged on a carrier sheet in such a way that no gas regions are formed which are greater than about 1 inch from the furnace wall surface or external surface of the material being processed. The substrate material preferably is a high surface area material. The starting surface area of the substrate material is preferably greater than about 250 cm²/g. In one embodiment, the starting surface area of the substrate material to be processed is in the range from about 1,000 cm²/g to about 10,000 cm²/g. Preferably, the starting substrate material is a high surface area, woven two-dimensional fabric.

The material that is used to manufacture the starting substrate material includes, for example, inorganic fibers and, optionally, inorganic fiber whiskers. Suitable inorganic fibers used to prepare the starting substrate material can be selected from carbon or graphite fibers, ceramic fibers such as silicon carbide, boron nitride, silicon nitride, alumina and aluminosilicate fibers, high temperature resistant glass fibers such as quartz fibers, refractory metal fibers and mixtures thereof. Useful carbon fibers are derived from a precursor material selected from PAN, petroleum pitch and rayon. In one embodiment, the fibers used to prepare the starting substrate material include carbon or graphite fibers and ceramic fibers. Preferably, the fibers used to prepare the starting fibrous substrate material are carbon fibers.

As described above, the substrate material may include inorganic fibers and inorganic fiber whiskers. The term “inorganic whiskers” refers to any one of “fibrils,” “nanofibers,” “microfibers,” “filaments,” “fibroids,” “nanotubes,” “buckytubes,” and the like, being various fiber-like structures having very small length and diameters and a high surface area to volume ratio.

Inorganic whiskers that can be used to prepare the substrate material are carbon whiskers. Suitable carbon whiskers for use in the process, are vapor grown carbon whiskers having an average diameter from about 0.1 to about 0.2 microns, such as those prepared the method disclosed by U.S. Pat. No. 5,594,060 (Alig et al.)

Although vapor grown carbon whiskers are particularly useful in the process, the process is not limited only to the above mentioned vapor grown carbon whiskers and, thus, other types of carbon fibrils, filaments, fibroids, whiskers, microfibers and nanofibers meeting the composition and sizes defined above, including but not limited to those prepared by the methods disclosed by U.S. Pat. No. 5,374,415 (Alig et al.), U.S. Pat. No. 5,691,054 (Tennent et al) and U.S. Pat. No. 4,663,230 (Tennent) may comprise the carbon whisker component of substrate material densified or coated according to the process.

The inorganic whiskers can be incorporated into polymer fibers. Threads can then be created from these polymers, which can be later carbonized to form a composite fiber consisting of whiskers that are held together by the carbon fiber surrounding them. Alternatively, high surface area papers and felts containing a blend of inorganic fibers and inorganic fiber whiskers can be prepared, and the continuous process of the present invention can use to deposit pyrocarbon thereon. According to one embodiment, the starting substrate material includes carbon fibers and high surface area carbon fiber whiskers.

Ceramic whiskers may also be used to prepare the starting substrate material. The ceramic whiskers that may be used include, but are not limited to, silicon carbide, silicon nitride, titanium carbide, titanium nitride, silica, alumina, zirconia, ceria and glass whiskers. In one embodiment, the ceramic whiskers that are used are silicon carbide whiskers.

Prior to pyrocarbon deposition, woven fabrics of carbon fibers typically exhibit a density of about 0.4 g/cm³. According to the inventive process, it is possible to partially densify the non-woven fabric of carbon fibers to achieve a densification in the range of about 1.3 to about 1.4 g/cm³. Additionally, it is also possible to achieve a densification in the range of about 1.9 to about 2 g/cm³, thereby achieving almost total densification of the non-woven fabric.

During the deposition process, the substrate material should be directed through the furnace in such a manner that all substrate material surfaces are equally accessible to the process gas, and that all regions of gas within the carbon deposition region of the process furnace are within about 1 inch from the inner furnace walls or the exterior surfaces of the substrate materials. Under these parameters, a narrow high temperature deposition zone is created between the inner surfaces of the process furnace retort and the outer surfaces of the substrate material. In one embodiment, the carbon deposition region 16 walls do not exceed about ¼ inch (0.64 cm) from any outer surface of the substrate material being processed.

The process furnace is tailored such that the ratio of the substrate material surface area to the carbon deposition zone inner wall surface area is sufficiently high to cause substantially uniform deposition of pyrocarbon at least one of i) into pores of the substrate or ii) onto the surface of the substrate at the carbon decomposition temperature in preference to significant deposition on the inner wall surface of the deposition zone. Generally, the ratio of substrate material surface area to carbon deposition zone inner wall surface area is about 10:1.

The process furnace can be tailored to achieve a ratio of deposition of pyrocarbon on and/or in the high surface area substrate material in preference to the walls of the hot zone of the process furnace of from about 40:1 to about 50:1. To assist in achieving a reduction in the formation of carbonaceous soots and tars on the inner surface walls of the process furnace, a carbon deposition hot zone is provided, where the walls of the carbon deposition hot zone have a low surface area, so as not to provide additional surface area for the deposition of pyrocarbon on the walls of the hot zone, instead of depositing pyrocarbon on the substrate materials while present in the deposition hot zone, can be provided. Preferably, the surface area of the walls of the deposition hot zone of the process furnace should be limited substantially to the geometric surface area of the inner-facing surface of the walls.

A continuous roll of composite material can be prepared using the above process furnace and process. The continuous roll of composite material comprises an fibrous substrate having a pyrocarbon added thereon. The pyrocarbon is coated onto either the surfaces of the fibrous substrate and/or is infiltrated into the porosity of the fibrous substrate. In one embodiment, the pyrocarbon addition is deposited onto the surfaces of the fibrous substrate and infiltrated into the pores of the fibrous substrate.

By utilizing the above furnace and process, a continuous roll of composite material can be manufactured, where the variation in the mass of the pyrocarbon addition, that is, the variation in the mass of the pyrocarbon that is deposited onto and/or infiltrated into the fibrous substrate, is less than about 20 weight percent over the substantial length of the continuous roll. The process can be used to prepare continuous rolls of composite material, where the variation in the mass of the pyrocarbon addition of the composite material is less than about 10 weight percent, or even less than about 5 weight percent over the substantial length of the continuous roll. The variation in the mass of the pyrocarbon addition is determined by measuring sections of the composite material having the dimensions of 2 square feet taken at various positions along the length of the continuous roll.

### EXAMPLES

The following examples are set forth to further illustrate the various embodiments of the process and furnace. The examples should not be construed as limiting the present invention in any manner.

### Example 1

A furnace was fabricated comprising an electrical resistance heating zone, which was about 36 inches long, surrounding the central portion of a silicon carbide outer process tube which had a 6 inch inner diameter and was 72 inches long. Within the outer process tube was an inner graphite retort that was approximately 70 inches long. The inner retort had a rectangular cross section reaction zone which was 4.5 inches wide by 0.200 inch, with an inner cross section channel which extended the full length of the inner retort reaction zone. Approximately 2 inches from either end of the inner retort, in the top of the retort were ¾ inch tubing inlets which allowed process gas to be introduced at one end and exhaust gas to be removed at the opposite end. A partial blocking insert extending approximately 1 inch into the ends of this channel and which was 0.120 inch thick was inserted to reduce the material entrance and material exit regions. Covering flanges on the ends of the outer process tube provided for sealed entrance and exit of the gas inlet and exhaust tubing. In addition, these covering flanges had a slit opening approximately 0.250 inch wide and 5 inches long with a flexible “lip” seal which substantially sealed the slit opening but allowed the introduction and passage of thin substrate material into the outer retort. The slit openings at either end were aligned with the openings in the inner retort so that a stiff thin material can travel though the system without interference, bending, or binding. In addition, provision was made at one end flange to introduce a purge gas directly into the region between the outer process tube and the inner process retort.

A roll of carbon fiber fabric, approximately 0.040 inches thick and 4.25 inches wide, with a friction tension drag, provided a continuous supply of fabric. The fabric was passed into the first lip seal, into the inner process retort, through the retort and out the opposite end of the retort, though the outer lip seal, and onto a receiving platform. Attached to the end of this strip of fabric was a pulling mechanism pulled by a constant speed motor and gear system to cause the material to travel through the system at a controlled rate of speed. The furnace was heated to 1100° C. while passing 15 slm of nitrogen through the purge gas inlet and 1 slm (the abbreviation “slm” refers to a standard liter per minute, ie, a liter of gas at standard temperature and pressure.) of nitrogen through the process gas retort inlet tube. When the furnace was stabilized with an internal temperature of 1100° C., the process gas nitrogen was reduced to 0.570 slm and a flow of 0.125 slm of propane was added to the process gas flow. These flows of gas resulted in a differential pressure of 0.2 mbar between the process gas and the outer atmosphere and a differential pressure of 0.6 mbar between the purge gas and the atmosphere. This resulted in a positive differential pressure of 0.4 torr between the purge gas in the outer process tube area and the process gas in the inner process retort area, confining the process gas to the narrow rectangular cross section surrounding the fabric material being processed. The pulling mechanism was set to pull material through the inner process retort area at approximately 2 inches per hour. This set of conditions resulted in the production of a heavily densified fabric with a final density of 1.5-1.6 g/cc when the thickness of the fabric was reduced to 0.032 inches to remove outer low density fibrous fuzz from the fabric.

Examination of the retort inner walls following production of the desired material, showed that approximately 90% of the carbon deposition occurred within the first 6 inches of the hot zone, tapering to a very small rate of deposition (less than 1%) toward the end of the 36 inches long hot zone. This is an indication that essentially all of the available carbon had been removed from the process gas. Small amounts of sooty deposits in the cold end of the process tube is a further confirmation that most of the available hydrocarbon had been consumed. A further confirmation is obtained by comparing the increase in mass of the fabric over the process run with the mass of carbon provided through the process gas inlet. This calculation indicated that greater than 60% of the carbon was used. Theoretical evaluation of the propane reaction indicates that the propane rapidly converts to ethylene, carrying 66% of the carbon mass, and methane, carrying the other 33% of the carbon mass. These results are consistent with 100% use of the ethylene at 1100° C. while the methane is essentially unused. This test indicated that the effective time that infiltration of carbon occurs in the fabric as it travels through the hot zone is approximately 12 hours. This compares with between 300 and 400 hours traditionally required to produce the same deposition in a batch vacuum furnace, which is limited in its effective deposition conditions by the occurrence of side reactions avoided by the process.

### Example 2

The process furnace and retort arrangement, starting substrate material, and substrate material transport system that was utilized in Example 1 was also utilized in the deposition process of Example 2.

The process furnace was heated to 1100° C. while passing 35 slm of nitrogen through the purge gas inlet and 3 slm of nitrogen through the process gas retort inlet tube. When the furnace was stabilized to an internal temperature of 1100° C., the process gas nitrogen was reduced to 0 slm and a flow of 3 slm of propane was added to the process gas flow. These flows of gas resulted in a differential pressure of approximately 4.3 mbar between the process gas and the outer atmosphere and a differential pressure of 5.2 mbar between the purge gas and the atmosphere. This resulted in a positive differential pressure of 0.9 mbar between the purge gas in the outer process tube area and the process gas in the inner process retort area, confining the process gas to the narrow rectangular cross section surrounding the fabric material being processed.

In this test the pulling mechanism was turned off and the processing was limited to 11 minutes. Measurement of the variation in density of the material along the high temperature carbon deposition zone of the furnace, indicated that a deposition rate of 300% weight gain in the 11 minute processing period was sustained over approximately 12 inches of the 36 inch long high temperature carbon deposition zone. This data indicates that a material transport rate of 72 inches per hour under these process conditions would result in a product with a 300% weight gain and resulting is a fabric having a density of 1.4 g/cc. This processing rate is sufficient to produce 48 linear yards of material per 24 hour day.

In addition to the deposition of amorphous pyrocarbon, the process furnace and process of the present invention can be used to deposit inorganic materials having a crystalline structure on substrate materials. For example, the process and furnace of the present invention can be utilized to deposit highly ordered pyrolytic graphite on substantially flat substrate materials. The furnace and process can be used to deposit highly ordered pyrolytic graphite onto low surface area substrate materials.

The process furnace and chemical vapor deposition process provides several distinct advantages over the traditional batch vacuum furnace processes used to deposit pyrocarbon onto a substrate. For example, operating at ambient pressure eliminates the need for maintaining a vacuum system, including a vacuum chamber, pumps, valves, filters, and the like. This reduces the cost and operating expense of the system considerably.

Operating the process in a continuous manner eliminates the labor and time traditionally associated with cutting, stacking, loading, evacuating, heating, cooling, venting, and unloading the process furnace.

Continuous processing also guarantees that all material sees all parts of the process furnace at some time during processing, thereby greatly increasing the uniformity and control of product density. For example, it is common in batch processing to observe variations in product density of greater than 25% over all sheets processed in the same batch. The present process is capable of having a control of better than ±5% on the density of the product. Thus, it is possible to tailor the density of the final product by controlling the length of time the starting substrate is present in the deposition zone of the process furnace.

Operating the process in accordance with the above parameters, namely introducing the process gas and starting substrate material into the process furnace at a cold region of the process furnace and simultaneously heating the gas and the substrate material, results in immediate use of the solid pyrocarbon-forming process gases within the process furnace. This substantially eliminates the creation of carbon deposits on hot gas inlet surfaces.

Operating the system with the inner volume of the process furnace substantially filled with the process gas and substrate material minimizes the gas side reactions and greatly reduces the build-up of any appreciable amount of high molecular weight gas components, that would otherwise deposit as tars or soot in the downstream exhaust portion of the system.

The furnace and process greatly increases the utilization of the carbon in the hydrocarbon process gases, producing a higher hydrogen content in the exhaust gas. This not only reduces the cost of the process gas used, but also makes it possible to economically recover the hydrogen gas from the exhaust for other uses. For example, typical batch vacuum processes can only achieve up to about 5% utilization of the hydrocarbon in the process gas, with the remainder of the hydrocarbon being expelled as exhaust. In contrast, the inventive process results in the utilization of up to about 99% of the decomposable hydrocarbon in the process gas introduced into the process furnace.

A further advantage of the process is that a much richer carbon-containing gas mix and higher temperatures can be used to increase the carbon deposition rate, producing a useful product having a desired level of deposition of carbon on or in the product in minutes or hours instead of days or weeks. Such fast processing significantly reduces the size and cost of processing equipment required to achieve the same product throughput rate, thereby further reducing the cost of manufacturing of the product.

Therefore, an furnace and process is provided for efficient deposition of pyrocarbon on substantially flat substrate materials. The cost and performance advantages of the inventive process and apparatus, in comparison to traditional batch vacuum furnace processes and apparatus have been demonstrated, as shown above. It should be understood that the present invention is not limited to the specific embodiments described above, but includes the variations, modifications and equivalent embodiments that are defined below. The embodiments that are disclosed separately are not necessarily in the alternative, as various embodiments of the invention may be combined to provide the desired characteristics.

We claim:

1. A continuous process furnace for the deposition of carbon onto a substrate material comprising:
a pre-deposition zone for accepting the substrate material and contacting the substrate material with a process gas at a temperature below the carbon deposition temperature, wherein the process gas comprises a decomposable carbon-containing species;
a carbon deposition zone in communication with the pre-deposition zone, wherein the walls of the deposition zone are spaced apart from the surface of the substrate, when present, by a distance that is small enough to allow convective and diffusive transport of the process gas to the substrate to permit substantially uniform deposition of pyrocarbon at least one of i) into pores of the substrate or ii) onto the surface of the substrate at the carbon decomposition temperature in preference to the decomposition of the process gas to produce soot and tar.

2. The continuous process furnace of claim 1, further comprising
means for introducing the carbon-containing process gas into the pre-deposition zone;
means for moving substrate material into and out of the furnace;
means for heating the furnace; and
means for removing carbon-depleted process gas from the furnace.

3. The continuous process furnace of claim 1, further comprising a cooling zone in communication with and located downstream from the carbon deposition zone.

4. The continuous process furnace of claim 1, wherein the distance between the outer surfaces of the substrate material and the inner wall surface of the carbon deposition zone does not exceed about 1 inch.

5. The continuous process furnace of claim 4, wherein the distance between the outer surfaces of the substrate material and the inner wall surface of the carbon deposition zone does not exceed about ¼ inch.

6. The continuous process furnace of claim 1, wherein the ratio of the substrate material surface area to the carbon deposition zone inner wall surface area is sufficiently high to cause substantially uniform deposition of pyrocarbon at least one of i) into pores of the substrate or ii) onto the surface of the substrate at the carbon decomposition temperature in preference to significant deposition on the inner wall surface of the deposition zone.

7. The continuous process furnace of claim 1, wherein the walls of the carbon deposition zone comprise one of a heat resistant material and an oxidation resistant material.

8. The continuous process furnace of claim 7, wherein the heat resistant material is graphite.

9. The continuous process furnace of claim 7, wherein the oxidation resistant material is selected from the group consisting of high melting point glass, refractory ceramic, oxidation resistant metals and oxidation resistant metal alloys.

10. The continuous process furnace of claim 9, wherein the refractory ceramic is selected from the group consisting of alumina, mullite, silicon carbide, boron nitride, and silicon nitride.

11. The continuous process furnace of claim 9, wherein the high melting point glass is quartz.

12. The continuous process furnace of claim 9, wherein the oxidation resistant metal alloy is stainless steel.

13. The continuous process furnace of claim 2, wherein the means for introducing the carbon-containing process gas into the pre-deposition zone is selected from the group consisting of a tube and a pipe, or a tube or pipe fitted with heaters to avoid condensation of less volatile hydrocarbon gases.

14. The continuous process furnace of claim 2, wherein the means for moving substrate material into and out of the furnace is selected from reel to reel devices, conveyors, opposed rollers, and push-pull tables.

15. The continuous process furnace of claim 2, wherein the means for heating the furnace is selected from gas fired flame heaters, metallic electrical resistance heaters, and ceramic electrical resistance heaters.

16. The continuous process furnace of claim 2, wherein the means for removing carbon-depleted process gas from the furnace is selected from ventilated hoods, continuous exhaust tubes or pipes, and suction tubes or pipes.

17. The continuous process furnace of claim 1, wherein the substrate material is substantially flat and sheet-like.

18. The continuous process furnace of claim 2, wherein the continuous process furnace optionally further comprises an isolation zone upstream of the pre-deposition zone for excluding ambient atmosphere reactive species from the carbon deposition zone.

19. The continuous process furnace of claim 2, wherein the continuous process furnace optionally further comprises an isolation zone downstream of the carbon deposition zone for excluding carbon-depleted process gas from the ambient atmosphere.

20. The continuous process furnace of claim 18, wherein the isolation zone contain means for introducing inert gas at above ambient atmospheric pressure.

21. The continuous process furnace of claim 19, wherein the isolation zone contain means for introducing inert gas at above ambient atmospheric pressure.

22. The continuous process furnace of claim 1, wherein the carbon deposition zone, in cross section, is substantially rectangular or oval in cross section to accommodate a sheet-like substrate material.

23. The continuous process furnace of claim 1, wherein the carbon deposition zone, in cross section, is substantially in a U shape or inverted T shape to accommodate a correspondingly shaped substrate material.

24. A continuous process for the deposition of pyrocarbon at least one of i) into pores of a substrate material or ii) onto the surface of the substrate material comprising:
introducing the substrate material into a process furnace; the process furnace comprising
a pre-deposition zone for accepting the substrate material and,
a carbon deposition zone in communication with the pre-deposition zone, wherein the walls of the deposition zone are spaced apart from the surface of the substrate, when present, by a distance that is small enough to allow convective and diffusive transport of the process gas to the substrate to permit substantially uniform deposition of pyrocarbon at least one of i) into pores of the substrate material or ii) onto the surface of the substrate material at the carbon decomposition temperature in preference to the decomposition of the process gas to produce soot and tar;
introducing a process gas into the pre-deposition zone; and contacting the substrate material with the process gas at a temperature below the carbon deposition temperature, wherein the process gas comprises a decomposable carbon-containing species;
passing the substrate material to the carbon deposition zone and heating the deposition zone to a temperature sufficient to cause decomposition of the decomposable carbon-containing species and substantially uniform deposition of pyrocarbon at least one of in the pores of or on the surface of the substrate material.

25. The process of claim 24, wherein the decomposable carbon-containing species is selected from the group consisting of natural gas, ethane, ethylene, acetylene, propane, propylene, propyne, butane, pentane, cyclopentane, hexane, cyclohexane, and mixtures thereof.

26. The process of claim 24 including heating the carbon deposition zone to a temperature of at least about 900° C.

27. The process of claim 26 including heating the carbon deposition zone to a temperature of at least about 1,100° C.

28. The process of claim 24, wherein the substrate material comprises a substantially flat, sheet-like or a thin shape.

29. The process of claim 28, wherein the substrate material is in a form selected from the group consisting of a woven fabric, a knitted fabric, a non-woven fabric, a felt, blanket, mat and a paper.

30. The process of claim 24, wherein the substrate material comprises inorganic fibers and, optionally, inorganic fiber whiskers.

31. The process of claim 30, wherein the inorganic fibers are selected from the group consisting of carbon fibers, graphite fibers, ceramic fibers, high temperature resistant glass fibers and refractory metal fibers.

32. The process of claim 31, wherein the carbon fibers are derived from a precursor material selected from the group consisting of PAN, petroleum pitch and rayon.

33. The process of claim 31, wherein the ceramic fibers are selected from the group consisting of silicon carbide, boron nitride, silicon nitride, alumina and alumino-silicates.

34. The process of claim 30, wherein the inorganic fiber whiskers are selected from the group consisting of carbon whiskers and ceramic whiskers.

35. A substantially uniformly carbon-densified or carbon-coated substrate material product produced by a continuous carbon deposition process comprising:
introducing the substrate material into a process furnace; the process furnace comprising
a pre-deposition zone for accepting the substrate material and,
a carbon deposition zone in communication with the pre-deposition zone, wherein the walls of the deposition zone are spaced apart from the surface of the substrate, when present, by a distance that is small enough to allow convective and diffusive transport of the process gas to the substrate to permit substantially uniform deposition of pyrocarbon at least one of i) into pores of the substrate material or ii) onto the surface of the substrate material at the carbon decomposition temperature in preference to the decomposition of the process gas to produce soot or tar;
introducing a process gas into the pre-deposition zone; and contacting the substrate material with the process gas at a temperature below the carbon deposition temperature, wherein the process gas comprises a decomposable carbon-containing species;
passing the substrate material to the carbon deposition zone and heating the deposition zone to a temperature sufficient to cause decomposition of the decomposable carbon-containing species and substantially uniform deposition of pyrocarbon at least one of in the pores of or on the surface of the substrate material.

36. A coated nonporous substrate material having a highly ordered pyrolytic graphite coating produced by the process of claim 35.

37. A composite article comprising a carbon-coated or carbon-densified fibrous substrate material produced by the process of claim 35.

38. A composite article produced by the process of claim 37, wherein the fibrous substrate comprises inorganic fibers and, optionally, inorganic fiber whiskers.

39. The fibrous substrate material and resulting composite article produced by the process of claim 35, comprising a substantially flat, sheet-like or thin shape.

40. The fibrous substrate material and composite article produced by the process of claim 35, comprising a shaped structure of substantially uniform thickness.

41. A composite article produced by the process of claim 40, wherein the shaped structure is in the form of a U or a T.

42. A continuous roll composite material comprising a fibrous substrate having a pyrocarbon addition that is (i) coated onto the fibrous substrate and/or (ii) infiltrated into the porosity of the fibrous substrate, wherein the variation in the mass of the pyrocarbon addition is less than about 20 weight percent, as determined by measuring sections of the composite material having the dimensions of 2 square feet taken at various positions along the length of the continuous roll.

43. The continuous roll composite material of claim 42, wherein the variation in the mass of the pyrocarbon addition is less than about 10 weight percent.

44. The continuous roll composite material of claim 43, wherein the variation in the mass of the pyrocarbon addition is less than about 5 weight percent.

45. The continuous roll composite material of claim 42, wherein the fibrous substrate comprises one of inorganic fibers and inorganic fiber whiskers.

46. The continuous roll composite material of claim 42, wherein the fibrous substrate material comprises a substantially flat, sheet-like or a thin shape.

47. The continuous roll composite material of claim 46, wherein the fibrous substrate material is in a form selected from the group consisting of a woven fabric, a knitted fabric, a non-woven fabric, a felt, blanket, mat, web and a paper.

48. The continuous roll composite material of claim 42, wherein the fibrous substrate material comprises inorganic fibers and, optionally, inorganic fiber whiskers.

49. The continuous roll composite material of claim 48, wherein the inorganic fibers are selected from the group consisting of carbon fibers, graphite fibers, ceramic fibers, high temperature resistant glass fibers and refractory metal fibers.

50. The continuous roll composite material of claim 49, wherein the carbon fibers are derived from a precursor material selected from the group consisting of PAN, petroleum pitch and rayon.

51. The continuous roll composite material of claim 49, wherein the ceramic fibers are selected from the group consisting of silicon carbide, boron nitride, silicon nitride, alumina and alumino-silicates.

52. The continuous roll composite material of claim 48, wherein the inorganic fiber whiskers are selected from the group consisting of carbon whiskers and ceramic whiskers.
